(19) United States
(12) Patent Application Publication
(10) Pub. No.: US 2011/0260977 A1
(43) Pub. Date: Oct. 27, 2011

(54) KEYBOARD AND COMPUTING DEVICE FOR PROVIDING A SOFTWARE INPUT PANEL

(75) Inventors: Jeremy FRANK, London (CA); Paul David HEDLEY, Bancroft (CA)

(73) Assignee: PSION TEKLOGIX INC., Mississauga (CA)

(21) Appl. No.: 12/766,245

(22) Filed: Apr. 23, 2010

(51) Int. Cl. G06F 3/02; H03M 11/00

(52) U.S. Cl. 345/168; 341/22

(57) ABSTRACT

A keyboard and a computing device for use with the keyboard to provide a software input panel (SIP). The keyboard comprises a keypad, a memory comprising a data structure for storing SIP data for use by the computing device to provide the SIP, and an interface for communicatively coupling the keyboard to the computing device. The computing device comprises a touch screen, an interface for communicatively coupling the computing device to the keyboard, a processor, and a memory having statements and instructions stored therein for execution by the processor to receive SIP data and selections of keypad keys from the keyboard, display the SIP on the touch screen, receive selections of the SIP keys from the touch screen, and process the selections of the keypad keys and the SIP keys.

### FIELD OF THE INVENTION

The present disclosure relates to a keyboard and a computing device for use with the keyboard, and more particularly to a keyboard for providing software input panel data and a computing device for providing a software input panel based on the software input panel data.

### BACKGROUND OF THE INVENTION

The keyboard has been a dominant means for the entry of information by users since the advent of the typewriter and has been incorporated into a variety of electronic devices, such as, personal computers, calculators, cellular phones, personal digital assistant, etc.

The typical keyboard comprises a plurality of keys each having one or more associated functions. A key may be used for a plurality of functions by selecting the key in combination with one or more modifier keys. Typically, each function associated with a key is identified by a label located on or adjacent to the key. Where the keys are used for a plurality of functions, the number of labels identifying the functions associated with each key may overwhelm a user and make it difficult to locate a desired function on the keyboard.

Advances in touch screen technology have provided an alternative means for the entry of information by recognizing user touches of the touch screen at specific locations. Some touch screen enabled devices have taken the concept of the keyboard to provide “virtual keyboards” or “software input panels” (“SIP”). A SIP is a graphical representation of a keyboard displayed on a touch screen wherein a user may select a function by touching the graphical representation of a key displayed on the touch screen that is associated with the function. While touch screen and SIP technology have provided flexibility in the entry of information by users, many users prefer the tactile feeling of a traditional keyboard.

### SUMMARY OF THE INVENTION

The present disclosure provides, in part, a keyboard for providing software input panel data and a computing device for providing a software input panel based on the software input panel data.

In one of its aspects, the disclosure provides a keyboard for use with a computing device to provide a software input panel (SIP) comprising a plurality of SIP keys, the keyboard comprising: a keypad comprising a plurality of keypad keys; a memory comprising a data structure for storing SIP data for use by the computing device to provide the SIP; and an interface communicatively coupled to the keypad and the memory, the interface for communicatively coupling the keyboard to the computing device.

SIP data may identify the location of each SIP key on the SIP. The SIP data may further comprise label data identifying one or more functions associated with each SIP key.

Each SIP key may be associated with a keypad key and the SIP data may identify the position of each SIP key with respect to the other SIP keys on the SIP as the same as the position of keypad key associated with the SIP key with respect to the other keypad keys on the keypad.

The SIP data may further comprise a graphic of the keypad and the SIP data may identify the location of each SIP key on the graphic. The SIP data further comprise label data identifying one or more functions associated with each SIP key.

In another one of its aspects, the disclosure provides a computing device for use with a keyboard to provide a software input panel (SIP) comprising a plurality of SIP keys, the keyboard comprising a keypad having a plurality of keypad keys, a memory having a data structure for storing SIP data for use by the computing device to provide the SIP, and an interface for communicatively coupling the keyboard to the computing device, the computing device comprising: a touch screen for displaying the SIP and receiving selections of SIP keys by a user; the interface for communicatively coupling the computing device to the keyboard; a processor communicatively coupled to the touch screen and the interface; the memory communicatively coupled to the processor, the memory having statements and instructions stored therein for execution by the processor to: receive SIP data and selections of keypad keys from the keyboard; display the SIP on the touch screen; receive selections of the SIP keys from the touch screen; and process the selections of the keypad keys and the SIP keys.

The SIP data may identify the location of each SIP key on the SIP; displaying the SIP on the touch screen may further comprise displaying each SIP key at the location identified by the SIP data; and processing selections of the keypad keys and the SIP keys may further comprise identifying a selection of a SIP key as a selection of the location of the SIP key on the SIP identified in the SIP data.

The SIP data may further comprise label data identifying one or more functions associated with each SIP key, and displaying the SIP on the touch screen may further comprise displaying the label for each SIP key on the touch screen at the location of each SIP key on the SIP identified in the SIP data.

Each SIP key may be associated with a keypad key and the SIP data may identify the position of each SIP key with respect to the other SIP keys on the SIP as the same as the position of keypad key associated with the SIP key with respect to the other keypad keys on the keypad

The SIP data may further comprise a graphic of the keypad and the SIP data identifies the location of each SIP key on the graphic, and displaying the SIP on the touch screen may further comprise displaying the graphic on the touch screen.

The SIP data may further comprise label data identifying one or more functions associated with each SIP key, and displaying the SIP on the touch screen may further comprise displaying the label for each SIP key on the touch screen at the location of each SIP key on the SIP identified in the SIP data.

In another one of its aspects, the disclosure provides a computer readable medium having statements and instructions stored therein for execution by a computing device, the computing device for use with a keyboard to provide a software input panel (SIP) comprising a plurality of SIP keys, the keyboard comprising a keypad having a plurality of keypad keys, a memory having a data structure for storing SIP data for use by the computing device to provide the SIP, and an interface for communicatively coupling the keyboard to the computing device, the computing device comprising a touch screen for displaying the SIP and receiving selections of SIP keys by a user, an interface for communicatively coupling the computing device to the keyboard, and a processor communicatively coupled to the touch screen, the interface and the computer readable memory, the statements and instructions stored in the computer readable medium executed by the processor to: receive SIP data and selections of keypad keys from the keyboard; display the SIP on the touch screen; receive selections of the SIP keys from the touch screen; and process selections of the keypad keys and the SIP keys.

The SIP data may identify the location of each SIP key on the SIP; displaying the SIP on the touch screen may further comprise displaying each SIP key at the location identified by the SIP data; and processing selections of the keypad keys and the SIP keys may further comprise identifying a selection of a SIP key as a selection of the location of the SIP key on the SIP identified in the SIP data.

The SIP data may further comprise label data identifying one or more functions associated with each SIP key, and displaying the SIP on the touch screen may further comprise displaying the label for each SIP key on the touch screen at the location of each SIP key on the SIP identified in the SIP data.

Each SIP key may be associated with a keypad key and the SIP data may identify the position of each SIP key with respect to the other SIP keys on the SIP as the same as the position of keypad key associated with the SIP key with respect to the other keypad keys on the keypad.

The SIP data may further comprise a graphic of the keypad and the SIP data identifies the location of each SIP key on the graphic, and displaying the SIP on the touch screen may further comprise displaying the graphic on the touch screen.

The SIP data may further comprise label data identifying one or more functions associated with each SIP key, and displaying the SIP on the touch screen may further comprise displaying the label for each SIP key on the touch screen at the location of each SIP key on the SIP identified in the SIP data.

### BRIEF DESCRIPTION OF THE DRAWINGS

Embodiments of the invention will now be described by way of example only with reference to the following drawings in which:

FIG. 1 is a perspective view of a modular keyboard and a mobile computing device for use with the keyboard according to one embodiment.

FIG. 2 is a system diagram of the modular keyboard shown in FIG. 1.

FIG. 3 is a diagram of the memory structure of the modular keyboard shown in FIG. 1.

FIG. 4 is a system diagram of the mobile computing device shown in FIG. 1.

FIG. 5 is a diagram of the memory structure of the mobile computing device shown in FIG. 1.

FIG. 6a is a diagram of an exemplary keypad graphic stored in the memory of the mobile computing device shown in FIG. 1.

FIG. 6b is a diagram of a first exemplary SIP resulting from combining the keypad graphic shown in FIG. 6a with label data associated with a first input state of the mobile computing device shown in FIG. 1.

FIG. 6c is a diagram of a second exemplary SIP resulting from combining the keypad graphic shown in FIG. 6a with label data associated with a second input state of the mobile computing device shown in FIG. 1.

FIG. 7 is a logic diagram of a method of generating a SIP by the mobile computing device shown in FIG. 1.

FIG. 8 is a logic diagram of a method of identifying the selection of a SIP key on a SIP by the mobile computing device shown in FIG. 1.

FIG. 9 is a logic diagram of a method of synchronizing the computing device with the keyboard shown in FIG. 1.

### DETAILED DESCRIPTION OF THE PREFERRED EMBODIMENTS

The embodiments described herein relate to a keyboard and a computing device for use with the keyboard to provide a software input panel (“SIP”). Specifically, the keyboard provides SIP data that is used by the computing device to provide a SIP on a touch screen through which a user may input information.

Throughout the disclosure, “processor” may include one or more processors located at one more locations communicating through one or more networks, including without limitation, application specific circuits, programmable logic controllers, field programmable gate arrays, microcontrollers, microprocessors, virtual machines, electronic circuits and other processing devices known to one skilled in the art; “computer readable medium” or “memory” may include one or more computer readable mediums located at one more locations communicating through one or more networks, including without limitation, random access memory, flash memory, read only memory, hard disc drives, optical drives and optical drive media, flash drives, and other computer readable storage media known to one skilled in the art; “communications interface” or “communication” may be include any communication method known in the art, including, without limitation, wired communication, such as, for example, parallel interface, serial interface, USB, Ethernet, and FireWire, wireless communication, such as, for example, infrared, wireless USB, Bluetooth, and WiFi, and any combination of one or more of the foregoing; and “communicatively coupled” refers to communication between two devices and/or components, directly or through one or more intermediate devices and/or components, including without limitation, communication through one or more systems, networks, buffers, databases, or media.

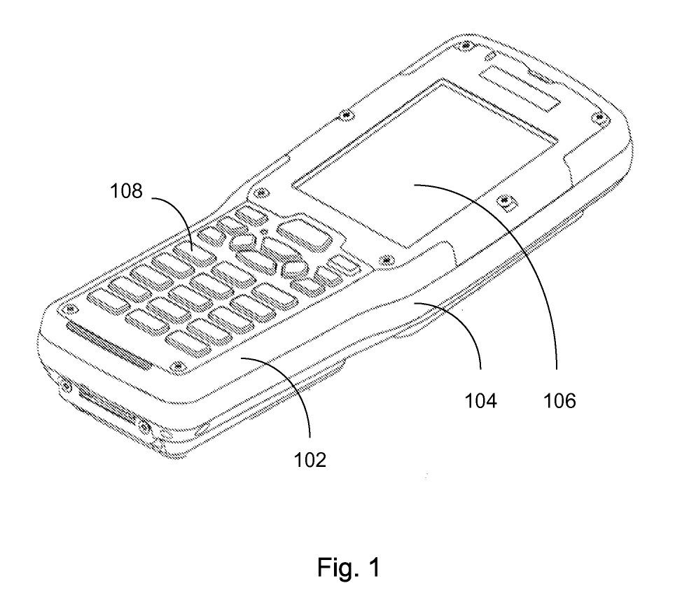

In one embodiment, a modular keyboard and a mobile computing device for use with the modular keyboard to provide a SIP is presented. Referring to FIG. 1, a keyboard 102 is shown detachably coupled to a mobile computing device 104.

### Keyboard

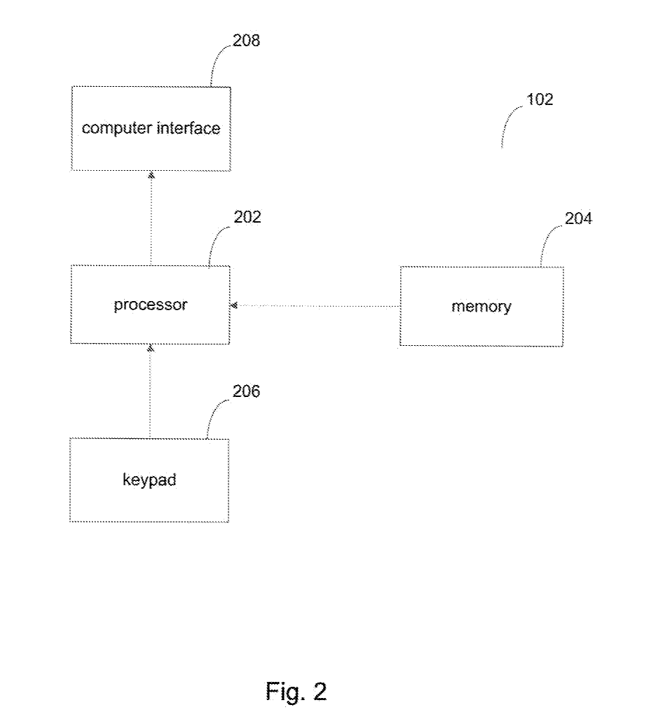

The keyboard 102 comprises a housing that is configured to detachably couple to the computing device 104. Referring to FIG. 2, the keyboard 102 further comprises a processor 202, a memory 204, a keypad 206, and a computer interface 208, all of which are supported by the housing. In the present embodiment the components 202, 204, 206, 208 of the keyboard 102 are described as separate standalone devices, however, it is to be understood that one or more of the components 202, 204, 206, 208 of the keyboard 102, or portions thereof, may be contained in one or more standalone devices.

The keypad 206 comprises an illumination module (not shown) and a plurality of keypad keys 108 (as shown in FIG. 1) that may be selected by a user. In the present embodiment, the keypad 206 comprises an elastomer keypad with carbon pill activators. In the alternative, the keypad 206 may comprise any other keypad technology known in the art, such as, a membrane, scissor-switch, dome-switched, capacitive, mechanical-switch, buckling spring, or Hall-effect. Each keypad key 108 may have one or more labels located on or adjacent to the key 108 identifying one or more functions associated with the key 108. In the present embodiment, a maximum of two labels are associated with each keypad key 108. In the alternative, more or less labels may be associated with each keypad key 108. Additional functions for each keypad key 108 may be provided through the use of the SIP associated with keyboard 102 as further described below. The illumination module comprises a plurality of light emitting diodes (LED) that may be activated to backlight the keypad 206. In the alternative, the illumination module may comprise other illumination devices and may illuminate specific keys or portions of the keypad 206.

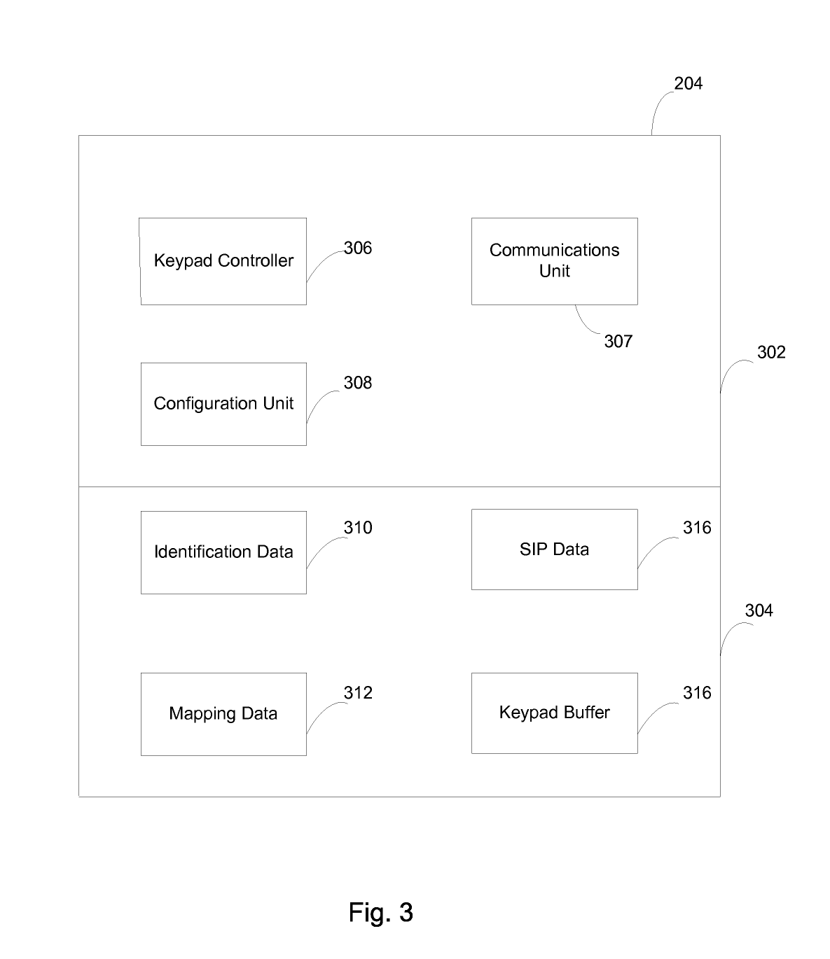

Referring to FIG. 3, the memory 204 comprises application memory 302 and data memory 304. The application memory 302 comprises instructions and statements for execution by the processor 202 to define a keypad controller 306, a configuration unit 308 and a communications unit 307, as further described below. The data memory 304 comprises data structures for storing identification data 310, mapping data 312 and SIP data 314 (collectively referred to as “configuration data”), and a keypad buffer 316. In the alternative, the data memory 304 comprises data structures for storing SIP data 314, but does not comprise data structures for storing mapping data 312 and/or identification data 310.

The identification data 310 comprises information that identifies the particular type of keyboard 102. In the present embodiment, the identification data 310 comprises a unique identifier for the particular type of keyboard 102. In the alternative, the identification data 310 may comprise other information identifying the type of keyboard and the capabilities of the keyboard (for example, keyboard name, keyboard serial number, keyboard version, whether the keyboard contains an illumination unit).

As will be further described below, upon the depression and release of a keypad key 108 by a user, the processor 202 generates a unique identifier associated with each selected key 108 known as a “key code”. The key code is used by the computing device 104 to identify which keypad keys 108 have been selected and determine which functions should be executed. The mapping data 312 provides information used by the computing device 104 to map a particular key code or series of key codes to a particular function. As further described below, the mapping data 312 may map a different function to the same key code or series of key codes depending on the input state of the computing device 104. For example, in a “default” input state of the computing device 104 the mapping data 312 for an exemplary set off key codes may be as follows:

TABLE 1

| Key Codes | Function |
|---|---|
| A0 | “a” |
| B0 | “b” |
| S0 A0 | “A” |
| S0 B0 | “B” |

In this input state, key codes A0 and B0 are each associated with separate keypad keys 108 and are mapped to the functions “a” and “b”, respectively. When the key pad key 108 associated with key code S0 is selected in combination with either of the keys 108 associated with key codes A0 and B0, the resultant functions are “A” and “B”, respectively. In this input state, the key pad key 108 associated with key code S0 is a “modifier key” equivalent to the “shift” function on a standard keyboard of a personal computer.

In a “caps lock” input state of the computing device 104, the mapping data 312 for the exemplary set key codes described in Table 1 above may be as follows:

TABLE 2

| Key Codes | Function |
|---|---|
| A0 | “A” |
| B0 | “B” |
| S0 A0 | “a” |
| S0 B0 | “b” |

In this input state, key codes A0 and B0 are each associated with separate keypad keys 108 and are mapped to the functions “A” and “B”, respectively, while the combination of either of these key codes with key code S0 associated with the modifier key described above maps to the functions “a” and “b”, respectively.

The SIP data 314 comprises information that is used by the computing device 104 to provide a SIP. As described above, a SIP is a graphical representation of a keyboard displayed on a touch screen wherein a user may select a function by touching the graphical representation of a key (referred to as a “SIP key”) displayed on the touch screen that is associated with the function. In the present embodiment, the layout of the SIP keys on the SIP is configured to match the layout of the keypad keys 108 on the keypad 206. Specifically, each keypad key 108 has an associated SIP key in the SIP that has at the same position in relation to other SIP keys as the associated key pad key 108 has on the keypad 206 in relation to other keys 108. Thus, the SIP is essentially a duplicate of the keypad. In the alternative, the layout of the SIP keys on the SIP may deviate from the layout of the keypad keys 108 on the keypad 206. In the further alternative, there may be more or less SIP keys in the SIP than there are keypad keys 108 on the keypad 206.

The SIP data 314 comprises a keypad graphic, SIP key identification data, key code data, and label data. In the alternative, the SIP data 314 comprises SIP key identification data but does not comprise a keypad graphic and/or key code data and/or label data. The keypad graphic comprises a graphical representation of the keypad 206 free of any labelling identifying the functions associated with a particular keypad key 108; the SIP key identification data comprises the identification and location of each SIP key on the keypad graphic; the key code data comprises the key code associated with each SIP key; and the label data provides alphanumeric text and/or graphics representing the functions associated with each SIP key for one or more input states of the computing device 104.

As stated above, in the present embodiment, each SIP key in the SIP is associated with a keypad key 108 in the keypad 206 and has the same position in relation to other SIP keys as the associated key pad key 108 has on the keypad 206 in relation to other keypad keys 108. In addition, each SIP key has key code data comprising the same key code as its associated keypad key 108. In this manner, a user may select either a SIP key or its associated key pad key 108 and produce the same key code resulting in the same function executed by the computing device 104. In the alternative, one or more SIP keys may have key code data comprising different key codes than their associated key pad keys 108. In the further alternative, one or more SIP keys may not be associated with a keypad key 108 and may have key code data comprising unique key codes as compared to other SIP keys and/or keypad keys 108.

Continuing with the example described above with respect to Tables 1 and 2, in a “default” input state of a computing device 104, the SIP data 314 for an exemplary SIP may be as follows (excluding the keypad graphic):

TABLE 3

| Key Code Data | SIP Key ID Data | Label Data |
|---|---|---|
| A0 | x1-x2, y1-y2 | “a” |
| B0 | x3-x4, y3-y4 | “b” |
| S0 | x5-x6, y5-y6 | shift.gif |

In a “caps lock” input state of the computing device 104, the SIP data 314 for the exemplary SIP may be as follows (excluding the keypad graphic)

TABLE 4

| Key Code Data | SIP key ID Data | Label Data |
|---|---|---|
| A0 | x1-x2, y1-y2 | “A” |
| B0 | x3-x4, y3-y4 | “B” |
| S0 | x5-x6, y5-y6 | shift.gif |

As can be seen from Tables 3 and 4, the label data associated with the SIP keys may change with changes in the input state of the computing device 102, however, the key code data and SIP key identification data associated with the SIP keys remain constant similar to the key codes and location of the keypad keys 108. In the present embodiment, the SIP key identification data associated with each SIP key is comprised of the boundaries of the SIP key in the keypad graphic, defined as a range of two-dimensional Cartesian coordinates. In the alternative, the SIP key identification data associated with each SIP key may comprises other information representing the location of the SIP key in the keypad graphic.

The label data may comprise separate alphanumeric text and/or graphics for each SIP key for each input state of the computing device 104. In the examples described above with respect to Tables 3 and 4, in the “default” input state, the label data associated with the SIP key having the key code “A0” comprises the alphanumeric text “a”, and the label data associated with SIP key having the key code “S0” comprises a graphic identified by the graphic file “shift.gif”. However, when the input state of the computing device changes to the “caps lock” input state, the label data associated with the SIP key having the key code “A0” changes to the alphanumeric text “A”, while the label data associated with the SIP key having the key code “S0” key code remains unchanged as a graphic identified by the graphic file “shift.gif”.

The keypad buffer 316 is configured to store key codes generated by the keyboard 102 representing the depression and release of keypad keys 108 by a user. The key codes are stored by the buffer 316 until they are removed by the computing device 104. The buffer 316 is a first-in-first-out queue that maintains the temporal order of key codes representing the depression and release of keys 108. Alternatively, the buffer 316 may comprise any type of data structure configured to store the depression and release of keypad keys 108 by a user.

The processor 202 is communicatively coupled to the memory 204, the keypad 206, and the computer interface 208. In the present embodiment the processor 202 is a PIC24FJ16GA004-I/ML made by Microchip Technology Inc. In the alternative, the processor 202 may be any processor capable of performing the functions of the processor 202 described herein.

The processor 202 executes instructions and statements stored in the memory 204 to define a keypad controller 306, a configuration unit 308 and a communications unit 307. The keypad controller 306 is responsible for (a) identifying and storing the depression and release of keypad keys 108 by a user, (b) directing the communications unit 307 to communicate the depression and release of keypad keys 108 to the computing device 104, and (c) executing control instructions received from the computing device 104. The configuration unit 308 is responsible for directing the communications unit 307 to communicate configuration data (identification data 310, mapping data 312, and SIP data 314) to the computing device 104. The communications unit 307 is responsible for communicating with the computing device 104 to send and receive information.

The keypad controller 306 identifies the depression and release of keypad keys 108 by a user (each referred to as a “key event”) by scanning the keypad 206 in response to a notification provided by the keypad 206 that a key event has occurred. In the alternative, the keypad controller 306 may periodically scan the keypad 206 for key events. The keypad controller 306 determines if the key event is valid by applying a debouncing filter to remove any undesired bouncing of the keys 108 which would otherwise be identified as separate key events. Once a valid key event is identified, the processor 202 stores the valid key event in the keypad buffer 316 of the memory 204 as a key code, and directs the communications unit 307 to signal the computing device 104 that a key event has occurred. The keypad controller 306 associates a unique key code with each key event of each keypad key 108 in order to distinguish individual keys 108 and associated key events (i.e. depression or release). The key codes are used by the computing device 104 to identify which keypad keys 108 have been depressed or released and determine which functions should be executed.

In addition, the keypad controller 306 executes control instructions received from the computing device 104. In the present embodiment, control instructions comprise activating or deactivating the illumination module of the keypad 206 to backlight the keypad 206. Alternatively, the control instructions may comprise any instructions that relate to the control of a particular keypad 206, such as, key repeat rate and other typomatic commands.

The configuration unit 308 handles requests for configuration data (identification data 310, mapping data 312, and SIP data 314) by the computing unit 104. Upon receiving a request for configuration data, the configuration unit 308 directs the communications unit 307 to communicate the requested configuration data to the computing device 104.

The communications unit 307 communicates with the computing device 104 through the computer interface 208 to exchange information. The communications unit 307 is responsible for packaging and unpacking information sent to and received from the computing device 104 in accordance with the communications protocols and communications mediums over which the communications are sent and received. In the present embodiment, the communications unit 307 utilizes the Serial Peripheral Interface communications standard to communicate with the computing device 104. In the alternative, the communications unit 307 may utilize any other communications medium or protocol known in the art.

The computer interface 208 (a) facilitates the communication of information between the keyboard 102 and computing device 104 when the keyboard 102 is coupled to the computing device 106, and (b) receives electrical power from the computing device 104 to power the keyboard 102. The computer interface 208 comprises a serial port interface that is communicatively coupled to the keyboard interface of the computing device 104 when the keyboard 102 is coupled to the computing device 104. In the alternative, the computer interface 208 may comprise any other communication interface known in the art.

In an alternative embodiment, the keyboard comprises a keypad, a memory, and a computer interface, but does not comprise a processor. The keypad is identical to the keypad 206 described above, except that the keypad 206 may notify a computing device through the computer interface that that a key event has occurred. The memory is identical to the memory 204 described above, except that the memory does not comprise application memory 304 and the memory is accessible by the computing device through the computer interface, without a processor serving as an intermediary. The computer interface is identical to the computer interface 208 described above, except that the computer interface is communicatively coupled to the keypad and the memory, without a processor serving as an intermediary.

In this embodiment, the computing device is identical to the computing device 104 described above, except that the computing device configured to read SIP data 314 from the memory of the keyboard and received notifications of key events from the keypad of the keyboard, without a keyboard processor serving as an intermediary. The computing device is responsible for scanning the keypad of the keyboard upon receipt of a notification that a key event has occurred and determining if the key event is a valid key event as described above.

### Computing Device

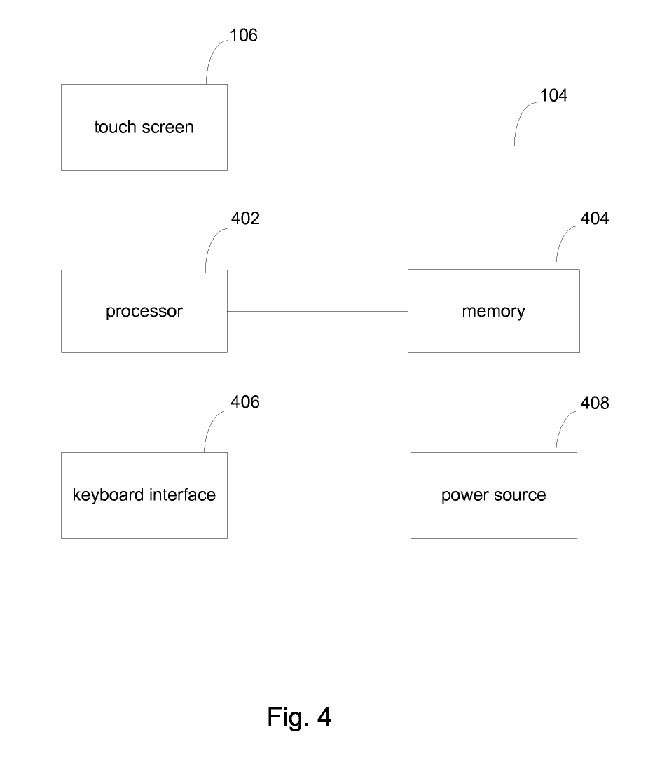

Referring to FIG. 1, the computing device 104 comprises a housing that is configured to detachably couple to the keyboard 102. Referring to FIG. 4, the computing device 104 further comprises a processor 402, a memory 404, a touch screen 106, a keyboard interface 406, and a power source 408. In the present embodiment the components 106, 402, 404, 406, 408 of the computing device 104 are described as being separate standalone devices, however, it is to be understood that one or more of the components 106, 402, 404, 406, 408 of the computing device 104, or portions thereof, may be contained in one or more standalone devices.

The touch screen 106 is an electronic display that can display information and detect the location of a user touch on the display. In the present embodiment, the touch screen 106 is a Sharp LS037V7DWO1 with touch panel. Alternatively, the touch screen 106 may be any other touch screen known in the art. The touch screen 106 is communicatively coupled to the processor 402 to display graphical information as directed by the processor 402 and communicate the location of touches on the touch screen 106 (each referred to as a “touch event”) to the processor 402. Upon the detection of a touch event, the touch screen 106 determines if the touch event is valid by comparing the duration and pressure of the touch event to a predetermined minimum threshold. Once a valid touch event is identified, the touch screen 106 stores the location of touch event on the touch screen 106 to a touch event buffer 516 in the memory 404 (described below), and updates the touch event buffer state of the state data 522 in the memory 404 (described below) to indicate that the touch event buffer 518 contains new touch event information.

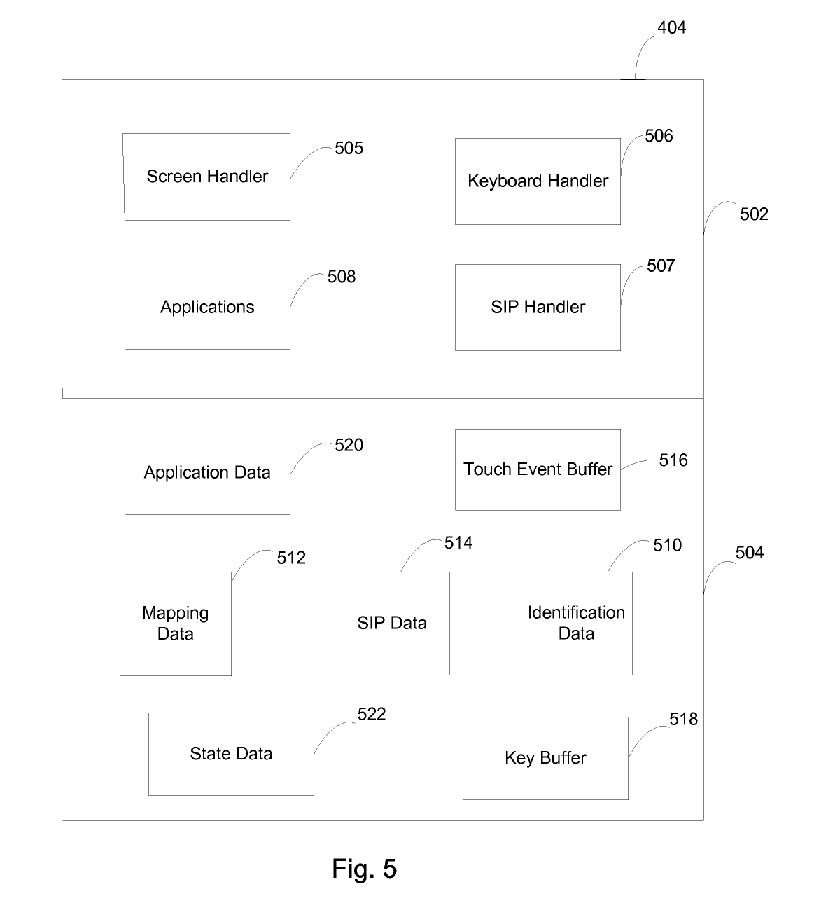

Referring to FIG. 5, the memory 404 comprises application memory 502 and data memory 504. The application memory 502 comprises instructions and statements for execution by the processor 402 to define a screen handler 505, a keyboard handler 506, a SIP handler 507 and applications 508, as further described below. The data memory 504 comprises data structures for storing identification data 510, mapping data 512 and SIP data 514 (collectively referred to as “configuration data”), and a touch event buffer 516, a key buffer 518, application data 520 and state data 522.

The touch event buffer 516 is configured to store the locations of touch events on the touch screen 106 until they are retrieved by the SIP handler 507. The buffer 516 is a first-in-first-out queue that maintains the temporal order of the touch events on the touch screen 106. Alternatively, the buffer 516 may comprise any type of data structure configured to store the location of the touches on the touch screen 106. In the further alternative, the touch event buffer 516 may be contained in the memory of the touch screen 106.

The key buffer 518 is configured to store the key codes associated with key events detected by the keyboard 102 and key codes associated with the selection of SIP keys on the touch screen 106 as detected by the SIP handler 507. The key buffer 518 stores the key codes until they are removed by applications 508. The buffer 518 is a first-in-first-out queue that maintains the temporal order of the key codes. Alternatively, the buffer 518 may any type of data structure for storing key codes.

The application data 520 comprises data that is used by applications 508 that are executed by the processor 402. The state data 522 comprises state information of the computing device 104. The state information comprises the touch event buffer state, key buffer state, input state, and other system states. The touch event buffer state indicates whether the touch event buffer 516 contains new touch event information; the key buffer state indicates whether the key buffer 518 contains new key codes; and the input state indicates how the selection of SIP keys on the touch screen 106 and detection of keypad events on the keyboard 102 should be interpreted (for example, caps lock, number lock, an other modified input states).

The configuration data is identical in form to the configuration data described above with respect to the keyboard 102. Namely, the identification data 510, mapping data 512 and SIP data 514 is identical in form to the identification data 310, mapping data 312 and SIP data 314, respectively. As further described below, during initialization of the computing device 104 and keyboard 102, the default configuration data in the memory 204 of the keyboard 102 is copied to the data structures for the configuration data in memory 404 of the computing device 104. However, during operation of the computing device 104, the default configuration data in the memory 404 may be customized as further described below.

The processor 402 is communicatively coupled to the memory 404, the touch screen 106, and the keyboard interface 406. In the present embodiment the processor 402 is a TI OMAP3515DCBC. In the alternative, the processor 402 may be any processor capable of performing the functions of the processor 402 described herein.

The processor 402 executes instructions and statements stored in the memory 404 to define a screen handler 505, a keyboard handler 506, a SIP handler 507, and applications 508. The screen handler 505 is responsible for communicating with the touch screen 106 to display graphics as directed by the applications 508; the keyboard handler 506 is responsible for communicating with the keyboard 102; the SIP handler 507 is responsible for generating a SIP for display on the touch screen 106 and identifying the selection of SIP keys on the touch screen 106; and the applications 508 are software applications that communicate with one or more of the screen handler 505, keyboard handler 506 and SIP handler 507.

The keyboard handler 506 utilizes the keyboard interface 406 to communicate control instructions to the keyboard 102 and acquires configuration data from the keyboard 102 at the direction of the applications 508. The keyboard handler 506 also acquires key codes associated with valid key events detected by the keyboard 102 upon the receipt of an indication from the keyboard 102 that a new valid key event has occurred. The keyboard handler 506 stores the key codes into the key buffer 518 and updates the key buffer state of the state data 522 to indicate that the key buffer 518 contains new key codes.

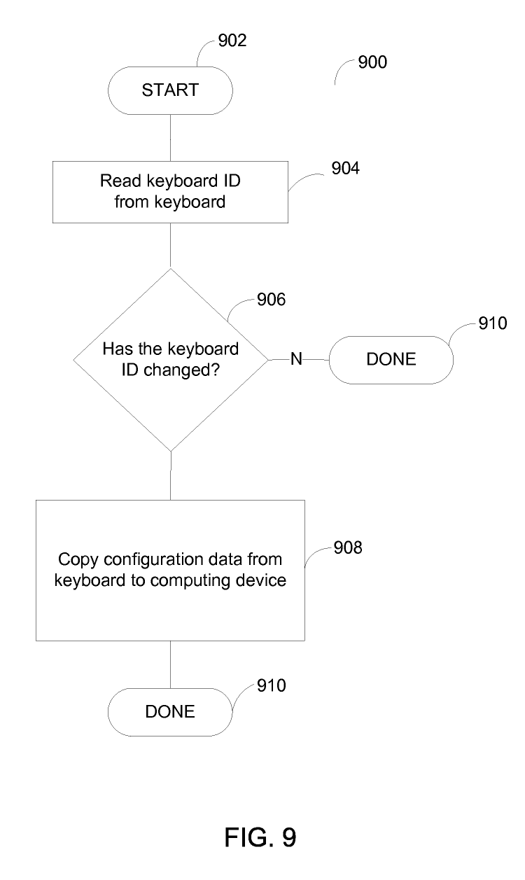

In addition, during the initialization of the computing device 104, and upon the initial coupling of the keyboard 102 to the computing device 104 where the computing device 104 is already activated, the keyboard handler 506 communicates with the keyboard 102 through the keyboard interface 406 to determine if a new keyboard 102 has been coupled to the computing device 104. If a new keyboard 102 has been coupled to the computing device 104, then the configuration data (identification data 510, mapping data 512 and SIP data 514) stored in the memory 404 is synchronized with the configuration data stored in the keyboard 102. Referring to FIG. 9, a logic diagram is provided describing a method 900 of synchronizing the computing device 104 with the keyboard 102 employed by the keyboard handler 506. In step 902 the keyboard handler 506 commences the method 900. The method 900 then advances to step 904 where the keyboard handler 506 communicates with the keyboard 102 through the keyboard interface 406 to acquire the keyboard identification 310 stored in the memory 204 of the keyboard 102. The method then advances to step 906 where the keyboard identification 310 of the keyboard 102 is compared to the current keyboard identification 510 stored in the memory 404 of the computing device 104. If the keyboard identifications 310, 501 are identical, the method advances to step 910 where the method 900 is terminated. If the keyboard identifications 310, 501 are different, the method 900 advances to step 908 where the keyboard handler 506 communicates with the keyboard 102 through the keyboard interface 406 to acquire the mapping data 312 and SIP data 314 stored in the memory 204 of the keyboard 102. The method 900 then stores the keyboard identification 310, the mapping data 312 and the SIP data 314 as the keyboard identification 510, the mapping data 512 and the SIP data 514, respectively, in the memory 404 of the computing device 104. The method then advances to step 910 where the method 900 is terminated.

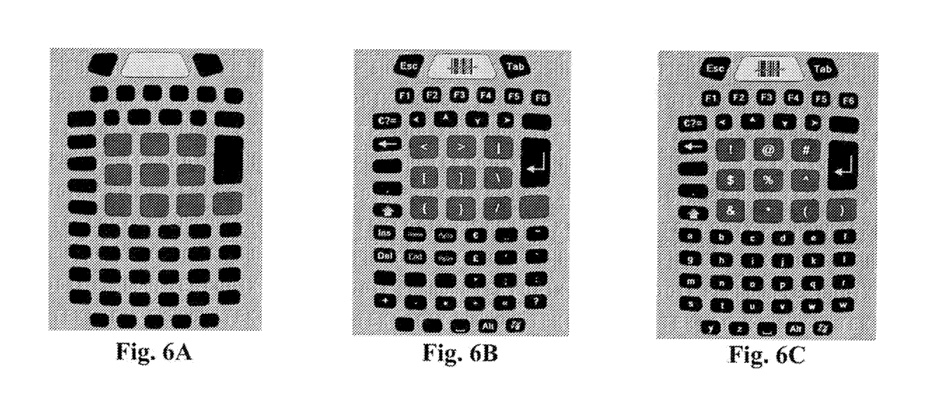

The SIP handler 507 generates a SIP for display on the touch screen 106 using the SIP data 514. When the SIP handler 507 is directed to generate a SIP by the applications 508, the SIP handler 507 identifies the current input state of the computing device 104 and then generates a SIP by overlaying the label data associated with each SIP key in the current input state onto the keypad graphic at the location of each SIP key identified in the SIP key identification data. FIGS. 6a to 6c provide examples of a keypad graphic and two SIPs for two different input states on the computing device 104. Referring to FIG. 6a, an exemplary keypad graphic is shown as item 600. The keypad graphic 600 provides a physical representation of the keypad 206 of the keyboard 102 without any labelling of the functions associated with the representations of each keypad key 108. Referring to FIG. 6b, an exemplary SIP for a first input state is shown as item 620. The SIP 620 is the result of overlaying the label data associated with each SIP key in the first input state onto the keypad graphic 600 shown in FIG. 6a. Referring to FIG. 6c, an exemplary SIP for a second input state is shown as item 640. The SIP 640 is the result of overlaying the label data associated with each SIP key in the second input state onto the keypad graphic 600 shown in FIG. 6a.

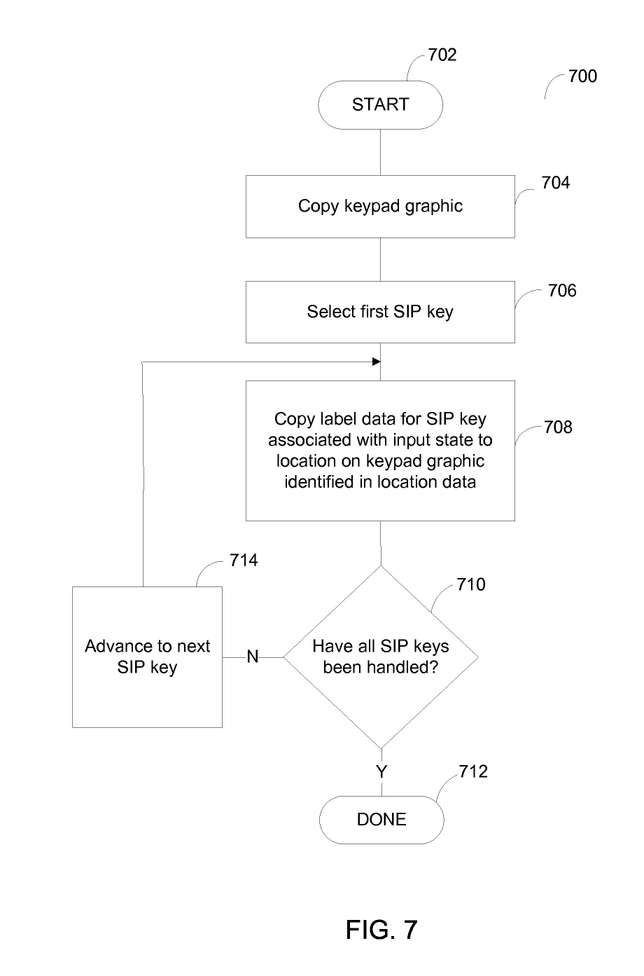

Referring to FIG. 7, a logic diagram is provided describing a method 700 of generating a SIP employed by the SIP handler 507. In step 702 the SIP handler 507 is requested to generate a SIP. The method 700 then advances to step 704 where the keypad graphic in the SIP data 514 is copied. The method 700 then advances to step 706 where the first SIP key identified by the SIP data 514 is selected as the current SIP key. The method 700 then advances to step 708 where the label data for the current input state of the computing device 104 in the SIP data 514 that is associated with the current SIP key is copied to the location on the copy of the keypad graphic identified by the SIP key identification data for the current SIP key in the SIP data 514. As described above, the label data may be alphanumeric text and/or graphics representing the functions associated with each SIP key in the current input state of the computing device 104. The method 700 then advances to step 710 where it is determined if all of the SIP keys in the SIP data 514 have been handled by the method 700. If all of the SIP keys have been handled by the method 700, the method 700 advances to step 712 where the method 700 is terminated, otherwise, the method 700 advances to step 714 where the next SIP key in the SIP data 514 is selected as the current SIP key and the method 700 repeats steps 708 to 710.

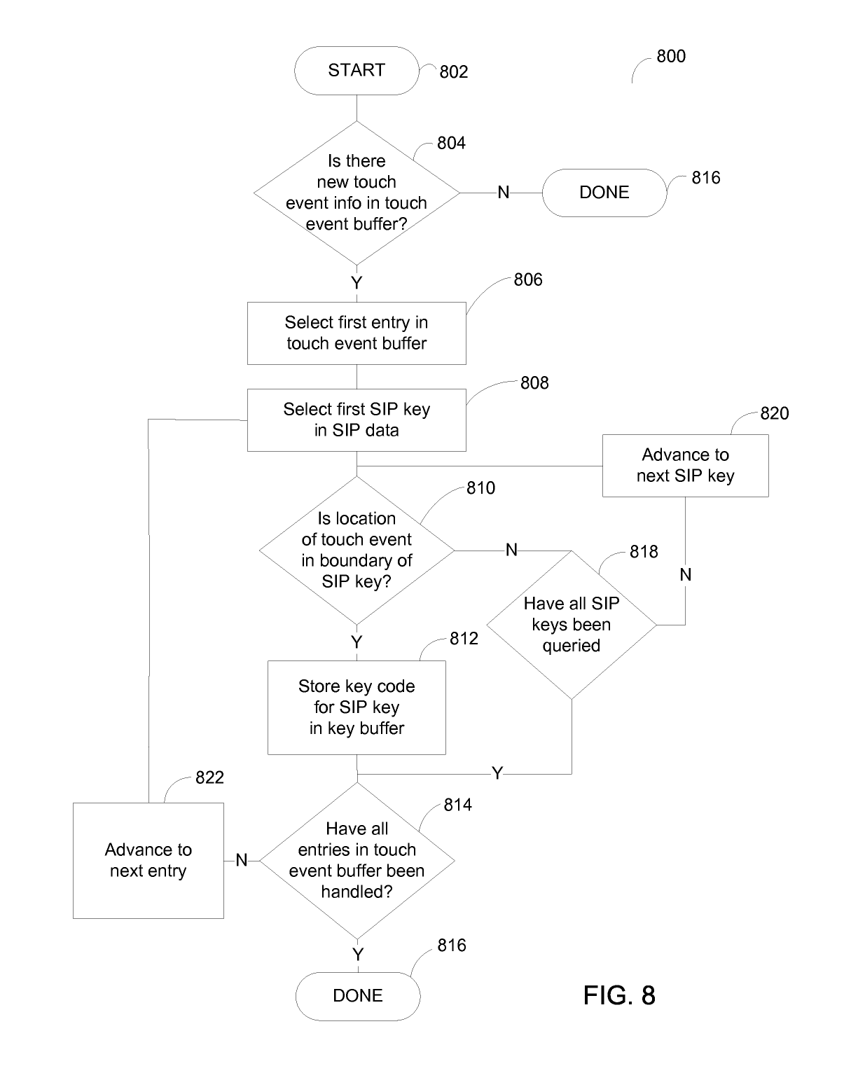

The SIP handler 507 also identifies the selection of SIP keys on the touch screen 106. Referring to FIG. 8, a logic diagram is provided describing a method 800 of identifying the selection of SIP keys on the touch screen 106 employed by the SIP handler 507. In step 802 the SIP handler 507 commences method 800. The method 800 then advances to step 804 where the touch event buffer state of the state data 522 is accessed to determine if new touch event information is present in the touch event buffer 516. If new touch event information is present in the touch event buffer 516, the method 800 advances to step 806, otherwise, the method 800 advances to step 816 where the method 800 is terminated. In step 806 the method 800 selects the first new entry in the touch event buffer 516 as the current touch event buffer entry. The method 800 then advances to step 808 where the first SIP key identified by the SIP data 514 is selected as the current SIP key. The method 800 then advances to step 810 where the location of the current touch event entry is compared to the boundaries of the SIP key identification data in the SIP data 514 associated with the current SIP key. If the location of the current touch event entry is within the boundaries of the locations data of the current SIP key, the method 800 advances to step 812, otherwise, the method 800 advances to step 818.

In step 812 the key code data in the SIP data 514 associated with the current SIP key is stored as a new entry in the key buffer 518 and the key buffer state of the state data 522 is updated to indicate that the key buffer 518 contains new key codes. The method 800 then advances to step 814 where it is determined if all of the new entries in the touch event buffer 516 have been serviced by method 800. If all of the new entries have been serviced, the method 800 advances to step 816 where the method 800 is terminated, otherwise, the method advances to step 822. In step 822 the method 800 selects the next entry in the touch event buffer 516 as the current touch event buffer entry and the method advances to step 808.

In step 818, the method 800 determines if all of the SIP keys in the SIP data 514 have been queried. If all of the SIP keys have been queried, the method 800 advances to step 814, otherwise, the method 800 advances to step 820 where the next SIP key in the SIP data 514 is selected as the current SIP key and the method 800 advances to step 810.

The keyboard interface 406 (a) facilitates the communication of information between the keyboard 102 and computing device 104 when the keyboard 102 is coupled to the computing device 104, and (b) provides electrical power to the keyboard 102 when the keyboard 102 is coupled to the computing device 104. The computing device 104 communicates with and provides power to the keyboard 102 by communicatively coupling the keyboard interface 406 of the computing device 102 to the computer interface 208 of the keyboard 102. The keyboard interface 406 comprises a serial port interface that is communicatively coupled to a computer interface 208 of the keyboard device 102 when the keyboard 102 is coupled to the computing device 104. In the alternative, the keyboard interface 406 may comprise any other communication interface known in the art.

The power source 408 provides electrical power to all of the elements of the computing device. In the present embodiment, the power source comprises battery cells. In the alternative, the power source 408 may be any other source of electrical power known in the art.

While particular embodiments of the present invention has been described in the foregoing, it is to be understood that other embodiments are possible within the scope of the invention and are intended to be included herein. It will be clear to any person skilled in the art that modifications of and adjustments to this invention, not shown, are possible without departing from the spirit of the invention as demonstrated through the exemplary embodiment. The invention is therefore to be considered limited solely by the scope of the appended claims.

1. A keyboard for use with a computing device to provide a software input panel (SIP) comprising a plurality of SIP keys, the keyboard comprising:
(a) a keypad comprising a plurality of keypad keys;
(b) a memory comprising a data structure for storing SIP data for use by the computing device to provide the SIP; and
(c) an interface communicatively coupled to the keypad and the memory, the interface for communicatively coupling the keyboard to the computing device.

2. The keyboard of claim 1 wherein the SIP data identifies the location of each SIP key on the SIP.

3. The keyboard of claim 2 wherein the SIP data further comprises label data identifying one or more functions associated with each SIP key.

4. The keyboard of claim 2 wherein each SIP key is associated with a keypad key and the SIP data identifies the position of each SIP key with respect to the other SIP keys on the SIP as the same as the position of keypad key associated with the SIP key with respect to the other keypad keys on the keypad.

5. The keyboard of claim 4 wherein the SIP data further comprises a graphic of the keypad and the SIP data identifies the location of each SIP key on the graphic.

6. The keyboard of claim 5 wherein the SIP data further comprises label data identifying one or more functions associated with each SIP key.

7. A computing device for use with a keyboard to provide a software input panel (SIP) comprising a plurality of SIP keys, the keyboard comprising a keypad having a plurality of keypad keys, a memory having a data structure for storing SIP data for use by the computing device to provide the SIP, and an interface for communicatively coupling the keyboard to the computing device, the computing device comprising:
(a) a touch screen for displaying the SIP and receiving selections of SIP keys by a user;
(b) an interface for communicatively coupling the computing device to the keyboard;
(c) a processor communicatively coupled to the touch screen and the interface;
(d) a memory communicatively coupled to the processor, the memory having statements and instructions stored therein for execution by the processor to:
(i) receive SIP data and selections of keypad keys from the keyboard;
(ii) display the SIP on the touch screen;
(iii) receive selections of the SIP keys from the touch screen; and
(iv) process the selections of the keypad keys and the SIP keys.

8. The computing device of claim 7 wherein:
(a) the SIP data identifies the location of each SIP key on the SIP;
(b) displaying the SIP on the touch screen further comprises displaying each SIP key at the location identified by the SIP data; and
(c) processing selections of the keypad keys and the SIP keys further comprises identifying a selection of a SIP key as a selection of the location of the SIP key on the SIP identified in the SIP data.

9. The computing device of claim 8 wherein:
(a) the SIP data further comprises label data identifying one or more functions associated with each SIP key; and
(b) displaying the SIP on the touch screen further comprises displaying the label for each SIP key on the touch screen at the location of each SIP key on the SIP identified in the SIP data.

10. The computing device of claim 8 wherein each SIP key is associated with a keypad key and the SIP data identifies the position of each SIP key with respect to the other SIP keys on the SIP as the same as the position of keypad key associated with the SIP key with respect to the other keypad keys on the keypad

11. The computing device of claim 10 wherein:
(a) the SIP data further comprises a graphic of the keypad and the SIP data identifies the location of each SIP key on the graphic; and
(b) displaying the SIP on the touch screen further comprises displaying the graphic on the touch screen.

12. The computing device of claim 11 wherein:
(a) the SIP data further comprises label data identifying one or more functions associated with each SIP key; and
(b) displaying the SIP on the touch screen further comprises displaying the label for each SIP key on the touch screen at the location of each SIP key on the SIP identified in the SIP data.

13. A computer readable medium having statements and instructions stored therein for execution by a computing device, the computing device for use with a keyboard to provide a software input panel (SIP) comprising a plurality of SIP keys, the keyboard comprising a keypad having a plurality of keypad keys, a memory having a data structure for storing SIP data for use by the computing device to provide the SIP, and an interface for communicatively coupling the keyboard to the computing device, the computing device comprising a touch screen for displaying the SIP and receiving selections of SIP keys by a user, an interface for communicatively coupling the computing device to the keyboard, and a processor communicatively coupled to the touch screen, the interface and the computer readable memory, the statements and instructions stored in the computer readable medium executed by the processor to:
(a) receive SIP data and selections of keypad keys from the keyboard;
(b) display the SIP on the touch screen;
(c) receive selections of the SIP keys from the touch screen; and
(d) process selections of the keypad keys and the SIP keys.

14. The computer readable medium of claim 13 wherein:
(a) the SIP data identifies the location of each SIP key on the SIP;
(b) displaying the SIP on the touch screen further comprises displaying each SIP key at the location identified by the SIP data; and
(c) processing selections of the keypad keys and the SIP keys further comprises identifying a selection of a SIP key as a selection of the location of the SIP key on the SIP identified in the SIP data.

15. The computer readable medium of claim 14 wherein:
(a) the SIP data further comprises label data identifying one or more functions associated with each SIP key; and
(b) displaying the SIP on the touch screen further comprises displaying the label for each SIP key on the touch screen at the location of each SIP key on the SIP identified in the SIP data.

16. The computer readable medium of claim 14 wherein each SIP key is associated with a keypad key and the SIP data identifies the position of each SIP key with respect to the other SIP keys on the SIP as the same as the position of keypad key associated with the SIP key with respect to the other keypad keys on the keypad.

17. The computer readable medium of claim 16 wherein:
(a) the SIP data further comprises a graphic of the keypad and the SIP data identifies the location of each SIP key on the graphic; and
(b) displaying the SIP on the touch screen further comprises displaying the graphic on the touch screen.

18. The computing device of claim 17 wherein:
(a) the SIP data further comprises label data identifying one or more functions associated with each SIP key; and
(b) displaying the SIP on the touch screen further comprises displaying the label for each SIP key on the touch screen at the location of each SIP key on the SIP identified in the SIP data.
